(19) United States
(12) Patent Application Publication
(10) Pub. No.: US 2020/0203398 A1
(43) Pub. Date: Jun. 25, 2020

(54) LOW TEMPERATURE POLY-SILICON (LTPS) DISPLAY PANEL MANUFACTURING METHOD

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yi JIANG, Wuhan, Hubei (CN)

(21) Appl. No.: 16/349,657

(22) PCT Filed: Mar. 15, 2019
(86) PCT No.: PCT/CN2019/078291

§ 371 Date: May 14, 2019

(30) Foreign Application Priority Data
Dec. 3, 2018 (CN) 201811466799.8

(51) Int. Cl. H01L 27/12; H01L 21/02; H01L 21/67

(52) U.S. Cl. CPC H01L 27/1274; H01L 21/02164; H01L 21/0217; H01L 21/022; H01L 21/02532; H01L 27/1262; H01L 21/02675; H01L 21/67017; H01L 21/02057; H01L 27/1218; H01L 21/02592

(57) ABSTRACT

A low temperature poly-silicon (LTPS) display panel manufacturing method, including: providing a vacuum environment; providing a glass substrate; forming a lower silicon monoxide layer on the glass substrate; forming a silicon nitride layer on the lower silicon monoxide layer; forming an upper silicon monoxide layer on the silicon nitride layer; forming an amorphous silicon layer on the upper silicon monoxide layer under the vacuum environment; forming a protective layer on the amorphous silicon layer; implementing an excimer-laser annealing (ELA) process to the amorphous silicon layer to form poly-silicon on the amorphous silicon layer. The present invention can prevent the issue that the amorphous silicon layer is attached with residual particles from the air or metal ions and results in that a crystal lattice of the poly-silicon formed from the amorphous silicon layer by the ELA process has defects.

### FIELD OF INVENTION

The present invention relates to a low temperature poly-silicon (LTPS) display panel manufacturing method, which can prevent an issue that before an amorphous silicon (a-Si) layer is implemented with an excimer-laser annealing (ELA) process, an amorphous silicon layer is attached with residual particles from the air or metal ions and results in that a crystal lattice of poly-silicon formed from the amorphous silicon layer by the ELA process has defects and lowers a yield rate of display panels.

### BACKGROUND OF INVENTION

Low temperature poly-silicon (LTPS) displays are thin film transistor liquid crystal displays (TFT-LCDs) of a new generation, a main difference of technology of the LTPS displays from that of conventional amorphous silicon displays lies in that the LTPS has advantages such as a fast response rate, high brightness, high resolution, and low power consumption.

During manufacture processes of a low temperature poly-silicon (LTPS) display panel, it is required to form poly-silicon (Poly-Si) on an amorphous silicon (a-Si) layer by an excimer-laser annealing (ELA) process. Before implementation of the ELA process, it is necessary to clean a surface of the amorphous silicon (a-Si) to improve electronic characteristics of thin film transistors.

A conventional ELA process is implemented under a general atmosphere environment and cannot prevent particles or metal ions from attaching to the amorphous silicon layer due to airflow. Therefore, during the ELA process, it is essential to utilize hydrofluoric acid and ozone (HF+O₃) to clean the surface of the amorphous silicon layer to prevent residual particles or metal ions. If any residual particles or metal ions remain on the surface of the amorphous silicon layer, the surface of the amorphous silicon layer will easily oxidize, and when the amorphous silicon layer is laser-crystalized to form poly-silicon, the residual particles or metal ions on the amorphous silicon layer receive laser energy and result in defects of a poly-silicon crystal lattice on the amorphous silicon layer, which influences uniformity of electronic characteristics of the LTPS product.

Furthermore, defective uneven structures exist on a natural oxide layer on the surface of the amorphous silicon layer, the defective uneven structures are also removed by the above hydrofluoric acid (HF), and then a silicon oxide (SiO) cover layer is formed on the surface of the cleaned amorphous silicon layer by O₃. However, because a hydrofluoric acid cleaning step is implemented under a general atmosphere environment, it is hard to prevent particles or metal ions from attaching to the surface of the amorphous silicon layer after the cleaning step, and employing the hydrofluoric acid easily results in contamination of products and environment.

Therefore, it is necessary to provide a LTPS display panel manufacturing method to solve the existed technical issue of the prior art.

### SUMMARY OF INVENTION

### Technical Issue

As described above, the present invention provides a low temperature poly-silicon (LTPS) display panel manufacturing method that can prevent an issue that before an amorphous silicon (a-Si) layer is implemented with an excimer-laser annealing (ELA) process, the amorphous silicon layer is attached with residual particles from the air or metal ions and results in that a crystal lattice of a poly-silicon formed from the amorphous silicon layer by the ELA process has defects and lowers a yield rate of the display panels.

### Technical Solution

A main objective of the present invention is to provide a low temperature poly-silicon (LTPS) display panel manufacturing method, comprising:

a vacuum environment providing step, comprising providing a vacuum environment;

a substrate providing step, comprising providing a glass substrate;

a lower silicon monoxide layer forming step, comprising forming a lower silicon monoxide layer on the glass substrate;

a silicon nitride layer forming step, comprising forming a silicon nitride layer on the lower silicon monoxide layer;

an upper silicon monoxide layer forming step, comprising forming an upper silicon monoxide layer on the silicon nitride layer;

an amorphous silicon layer forming step, comprising forming an amorphous silicon layer on the upper silicon monoxide layer under the vacuum environment;

a protective layer forming step, comprising forming a protective layer on the amorphous silicon layer; and

an annealing step, comprising implementing an excimer-laser annealing (ELA) process to the amorphous silicon layer to form a poly-silicon on the amorphous silicon layer.

In an embodiment of the present invention, the protective layer forming step is implemented under the vacuum environment.

In an embodiment of the present invention, the annealing step is implemented under the vacuum environment.

In an embodiment of the present invention, the substrate providing step, at least one of the substrate providing step, the lower silicon monoxide layer forming step, the silicon nitride layer forming step, the upper silicon monoxide layer forming step, and the annealing step is implemented under the vacuum environment.

In an embodiment of the present invention, the substrate providing step, the lower silicon monoxide layer forming step, the silicon nitride layer forming step, and the upper silicon monoxide layer forming step are implemented under the vacuum environment.

In an embodiment of the present invention, the vacuum environment is a vacuum chamber.

In an embodiment of the present invention, the vacuum chamber is connected to a vacuum pump, and the vacuum pump is configured to create vacuum in the vacuum chamber.

In an embodiment of the present invention, the manufacturing method further comprises after the amorphous silicon layer forming step is implemented, cleaning the amorphous silicon layer by hydrofluoric acid and ozone, and then implementing the protective layer forming step.

In an embodiment of the present invention, the protective layer is silicon monoxide.

Another objective of the present invention is to provide a low temperature poly-silicon (LTPS) display panel manufacturing method, comprising:

a vacuum environment providing step, comprising providing a vacuum environment;

a substrate providing step, comprising providing a glass substrate;

a lower silicon monoxide layer forming step, comprising forming a lower silicon monoxide layer on the glass substrate;

a silicon nitride layer forming step, comprising forming a silicon nitride layer on the lower silicon monoxide layer;

an upper silicon monoxide layer forming step, comprising forming an upper silicon monoxide layer on the silicon nitride layer;

an amorphous silicon layer forming step, comprising forming an amorphous silicon layer on the upper silicon monoxide layer under the vacuum environment;

a protective layer forming step, comprising forming a protective layer on the amorphous silicon layer; and

an annealing step, comprising implementing an excimer-laser annealing (ELA) process to the amorphous silicon layer to form a poly-silicon on the amorphous silicon layer;

wherein the protective layer forming step is implemented under the vacuum environment;

wherein the annealing step is implemented under the vacuum environment;

wherein at least one of the substrate providing step, the lower silicon monoxide layer forming step, the silicon nitride layer forming step, the upper silicon monoxide layer forming step, and the annealing step is implemented under the vacuum environment.

In an embodiment of the present invention, the substrate providing step, the lower silicon monoxide layer forming step, the silicon nitride layer forming step, and the upper silicon monoxide layer forming step are implemented under the vacuum environment.

In an embodiment of the present invention, the vacuum environment is a vacuum chamber.

In an embodiment of the present invention, the vacuum chamber is connected to a vacuum pump, and the vacuum pump is configured to create vacuum in the vacuum chamber.

In an embodiment of the present invention, the manufacturing method further comprises after the amorphous silicon layer forming step is implemented, cleaning the amorphous silicon layer by hydrofluoric acid and ozone, and then implementing the protective layer forming step.

In an embodiment of the present invention, the protective layer is silicon monoxide.

### Advantages

Compared to the prior art, the low temperature poly-silicon (LTPS) display panel manufacturing method of the present invention, by at least implementing the amorphous silicon layer forming step under the vacuum environment instead of a general atmosphere environment, prevents an issue that before an amorphous silicon (a-Si) layer is implemented with an excimer-laser annealing (ELA) process, the amorphous silicon layer is attached with residual dust particles from the air or metal ions and results in that a crystal lattice of a poly-silicon formed from the amorphous silicon layer by the ELA process has defects and lowers a yield rate of the display panels.

Therefore, the LTPS display panel manufacturing method of the present invention, by the ELA step, forms a poly-silicon layer having a better arrangement structure of a crystal lattice compared to the prior art to prevent defects of the crystal lattice, which improves yield rate and quality of the display panel. Furthermore, after formation of the amorphous silicon layer, because residual particles and metal ions of the surface of the amorphous silicon layer are drastically decreased, the cleaning step utilizing hydrofluoric acid and ozone become unnecessary, which improves efficiency of the display panel manufacturing processes and lowers the environment contamination.

In order to make the above contents of the present invention more obvious and understandable, preferred embodiments are described in detail with reference to the drawings as follows.

### DESCRIPTION OF DRAWINGS

FIG. 1 is a schematic view of a low temperature poly-silicon (LTPS) display panel manufacturing method of the present invention implemented under a vacuum environment; and

FIG. 2 is a flowchart of the LTPS display panel manufacturing method of the present invention.

### DETAILED DESCRIPTION OF PREFERRED EMBODIMENTS

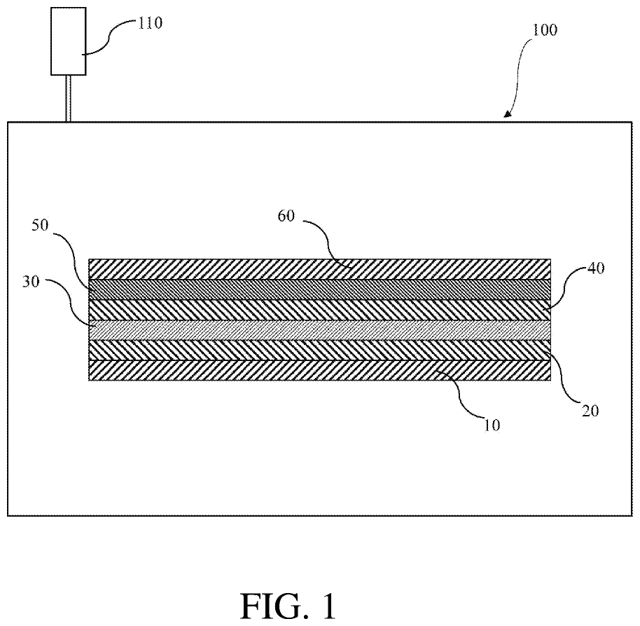

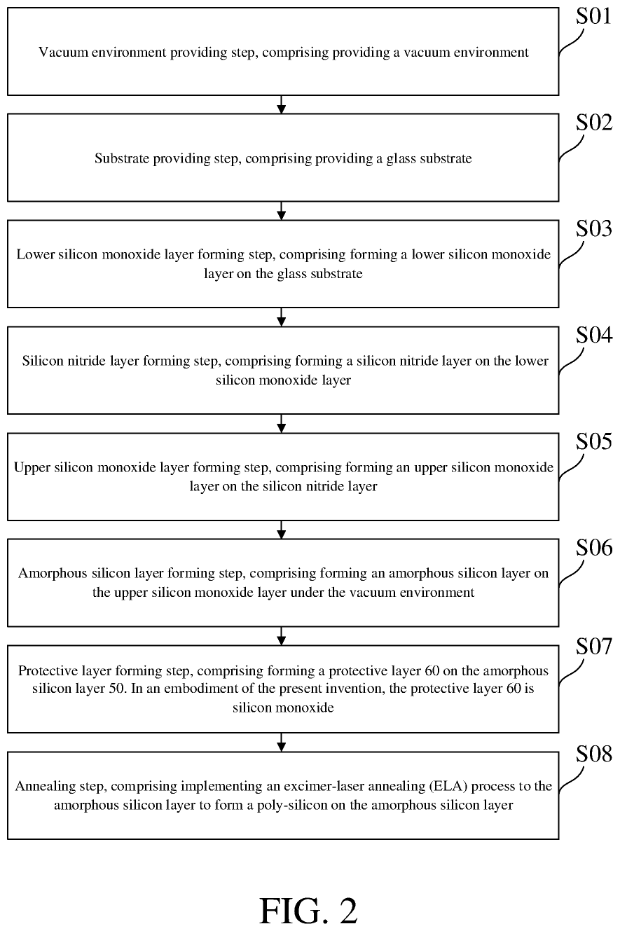

With reference to FIGS. 1 and 2, a low temperature poly-silicon (LTPS) display panel manufacturing method of the present invention comprises: a vacuum environment providing step S01, a substrate providing step S02, a lower silicon monoxide layer forming step S03, a silicon nitride layer forming step S04, an upper silicon monoxide layer forming step S05, an amorphous silicon layer forming step S06, a protective layer forming step S07, and an annealing step S08.

The vacuum environment providing step S01 comprises providing a vacuum environment 100. In an embodiment of the present invention, the vacuum environment 100 is a vacuum chamber. The vacuum chamber is connected to a vacuum pump 110, the vacuum pump 110 is configured to vacuum the vacuum chamber. The vacuum pump 110 can continuously vacuum the vacuum chamber throughout the manufacturing method to maintain the vacuum condition of the vacuum chamber. Alternatively, the vacuum pump 110 can selectively vacuum the vacuum chamber during specific one or more of the steps to efficiently maintain the vacuum condition of the vacuum chamber and prevent a power consumption issue due to continuous vacuuming.

The substrate providing step S02 comprises providing a glass substrate 10.

The lower silicon monoxide layer forming step S03 comprises forming a lower silicon monoxide layer 20 on the glass substrate 10.

The silicon nitride layer forming step S04 comprises forming a silicon nitride layer 30 on the lower silicon monoxide layer 20.

The upper silicon monoxide layer forming step S05 comprises forming an upper silicon monoxide layer 40 on the silicon nitride layer 30. In an embodiment of the present invention, the protective layer forming step S07 is implemented under the vacuum environment 100.

The amorphous silicon layer forming step S06 comprises under the vacuum environment 100, forming an amorphous silicon layer 50 on the upper silicon monoxide layer 40.

The protective layer forming step S07 comprises forming a protective layer 60 on the amorphous silicon layer 50. In an embodiment of the present invention, the protective layer 60 is silicon monoxide.

The annealing step S08 comprises implementing an excimer-laser annealing (ELA) process to the amorphous silicon layer 50 to form a poly-silicon (Poly-Si) on the amorphous silicon layer 50. In an embodiment of the present invention, the annealing step S08 is implemented under the vacuum environment 100. In an embodiment of the present invention, after the amorphous silicon layer forming step S06, the amorphous silicon layer 50 is cleaned by hydrofluoric acid and ozone, and then the protective layer forming step S07 is implemented.

In an embodiment of the present invention, at least one of the substrate providing step S02, the lower silicon monoxide layer forming step S03, the silicon nitride layer forming step S04, the upper silicon monoxide layer forming step S05, and the annealing step S08 is implemented under the vacuum environment 100.

In an embodiment of the present invention, the substrate providing step S02, the lower silicon monoxide layer forming step S03, the silicon nitride layer forming step S04, and the upper silicon monoxide layer forming step S05 are all implemented under the vacuum environment 100.

Compared to the prior art, the LTPS display panel manufacturing method of the present invention, by at least implementing the amorphous silicon layer forming step S06 under the vacuum environment 100 instead of a general atmosphere environment, prevents an issue that before an amorphous silicon (a-Si) layer is implemented with the ELA process, the amorphous silicon layer 50 is attached with residual dust particles from the air or metal ions and results in that a crystal lattice of poly-silicon formed from the amorphous silicon layer 50 by the ELA process has defects and lowers a yield rate of the display panels. Therefore, the LTPS display panel manufacturing method of the present invention, by the ELA step S08, forms a poly-silicon layer having a better arrangement structure of a crystal lattice compared to the prior art to prevent defects of the crystal lattice, which improves a yield rate and quality of the display panel. Furthermore, after formation of the amorphous silicon layer 50, because residual particles and metal ions of the surface of the amorphous silicon layer 50 are drastically decreased, the cleaning step utilizing hydrofluoric acid and ozone becomes unnecessary, which improves efficiency of the display panel manufacturing processes and lowers the environment contamination.

What is claimed is:

1. A low temperature poly-silicon (LTPS) display panel manufacturing method, comprising:
a vacuum environment providing step, comprising providing a vacuum environment;
a substrate providing step, comprising providing a glass substrate;
a lower silicon monoxide layer forming step, comprising forming a lower silicon monoxide layer on the glass substrate;
a silicon nitride layer forming step, comprising forming a silicon nitride layer on the lower silicon monoxide layer;
an upper silicon monoxide layer forming step, comprising forming an upper silicon monoxide layer on the silicon nitride layer;
an amorphous silicon layer forming step, comprising forming an amorphous silicon layer on the upper silicon monoxide layer under the vacuum environment;
a protective layer forming step, comprising forming a protective layer on the amorphous silicon layer; and
an annealing step, comprising implementing an excimer-laser annealing (ELA) process to the amorphous silicon layer to form poly-silicon on the amorphous silicon layer.

2. The LTPS display panel manufacturing method as claimed in claim 1, wherein the protective layer forming step is implemented under the vacuum environment.

3. The LTPS display panel manufacturing method as claimed in claim 1, wherein the annealing step is implemented under the vacuum environment.

4. The LTPS display panel manufacturing method as claimed in claim 1, wherein at least one of the substrate providing step, the lower silicon monoxide layer forming step, the silicon nitride layer forming step, the upper silicon monoxide layer forming step, and the annealing step is implemented under the vacuum environment.

5. The LTPS display panel manufacturing method as claimed in claim 1, wherein the substrate providing step, the lower silicon monoxide layer forming step, the silicon nitride layer forming step, and the upper silicon monoxide layer forming step are implemented under the vacuum environment.

6. The LTPS display panel manufacturing method as claimed in claim 1, wherein the vacuum environment is a vacuum chamber.

7. The LTPS display panel manufacturing method as claimed in claim 1, wherein the vacuum chamber is connected to a vacuum pump, and the vacuum pump is configured to create vacuum in the vacuum chamber.

8. The LTPS display panel manufacturing method as claimed in claim 1 further comprising after the amorphous silicon layer forming step is implemented, cleaning the amorphous silicon layer by hydrofluoric acid and ozone, and then implementing the protective layer forming step.

9. The LTPS display panel manufacturing method as claimed in claim 1, wherein the protective layer is silicon monoxide.

10. A low temperature poly-silicon (LTPS) display panel manufacturing method, comprising:
a vacuum environment providing step, comprising providing a vacuum environment;
a substrate providing step, comprising providing a glass substrate;
a lower silicon monoxide layer forming step, comprising forming a lower silicon monoxide layer on the glass substrate;
a silicon nitride layer forming step, comprising forming a silicon nitride layer on the lower silicon monoxide layer;
an upper silicon monoxide layer forming step, comprising forming an upper silicon monoxide layer on the silicon nitride layer;
an amorphous silicon layer forming step, comprising forming an amorphous silicon layer on the upper silicon monoxide layer under the vacuum environment;
a protective layer forming step, comprising forming a protective layer on the amorphous silicon layer; and
an annealing step, comprising implementing an excimer-laser annealing (ELA) process to the amorphous silicon layer to form poly-silicon on the amorphous silicon layer;
wherein the protective layer forming step is implemented under the vacuum environment;
wherein the annealing step is implemented under the vacuum environment;
wherein at least one of the substrate providing step, the lower silicon monoxide layer forming step, the silicon nitride layer forming step, the upper silicon monoxide layer forming step, and the annealing step is implemented under the vacuum environment.

11. The LTPS display panel manufacturing method as claimed in claim 10, wherein the substrate providing step, the lower silicon monoxide layer forming step, the silicon nitride layer forming step, and the upper silicon monoxide layer forming step are implemented under the vacuum environment.

12. The LTPS display panel manufacturing method as claimed in claim 10, wherein the vacuum environment is a vacuum chamber.

13. The LTPS display panel manufacturing method as claimed in claim 10, wherein the vacuum chamber is connected to a vacuum pump, and the vacuum pump is configured to create vacuum in the vacuum chamber.

14. The LTPS display panel manufacturing method as claimed in claim 10 further comprising after the amorphous silicon layer forming step is implemented, cleaning the amorphous silicon layer by hydrofluoric acid and ozone, and then implementing the protective layer forming step.

15. The LTPS display panel manufacturing method as claimed in claim 10, wherein the protective layer is silicon monoxide.
